(19) United States
(12) Patent Application Publication
(10) Pub. No.: US 2024/0411044 A1
(43) Pub. Date: Dec. 12, 2024

(54) AXLE COUNTING METHOD AND AXLE COUNTING SYSTEM

(71) Applicant: GTS Deutschland GmbH, DITZINGEN (DE)

(72) Inventors: Thomas Mack, Heimsheim (DE); Rainer Klemm, Steinheim (DE)

(73) Assignee: GTS Deutschland GmbH, DITZINGEN (DE)

(21) Appl. No.: 18/810,441

(22) Filed: Aug. 20, 2024

Related U.S. Application Data
(63) Continuation of application No. PCT/EP2023/054341, filed on Feb. 21, 2023.

(30) Foreign Application Priority Data
Feb. 22, 2022 (DE) 10 2022 201 840.0

(51) Int. Cl. G01V 3/12; B61L 1/16

(52) U.S. Cl. CPC G01V 3/12; B61L 1/161

(57) ABSTRACT

An axle counting method for rail-mounted vehicles is disclosed. An electromagnetic transmission signal with a frequency is produced, by a frequency source. The electromagnetic transmission signal is transmitted by means of a transmission device of an electromagnetic rail contact element. The electromagnetic transmission signal is detected as a first reception signal and a second reception signal by means of two spaced-apart receiving units of the rail contact element. The reception signals are transmitted. An evaluation signal is generated within a signal processing unit. To generate the transmission signal, a single transmission unit is used, and in that the reception signals received by the two receiving units originate from the same transmission signal.

### CROSS-REFERENCE TO RELATED APPLICATIONS

This continuation application claims priority to PCT/EP2023/054341 filed on Feb. 21, 2023, which has published as WO 2023/161239 A1 and also the German application number DE 10 2022 201 840.0 filed on Feb. 22, 2022, the entire contents of which are fully incorporated herein with these references.

### DESCRIPTION

### Field of the Invention

The invention relates to an axle counting method for rail-mounted vehicles, having the following method steps: producing an electromagnetic transmission signal with a frequency, by a frequency source; transmitting the electromagnetic transmission signal by means of a transmission device of an electromagnetic rail contact element; detecting the electromagnetic transmission signal as a first reception signal and a second reception signal by means of two spaced-apart receiving units of the rail contact element; transmitting the reception signals; and producing an evaluation signal within a signal processing unit.

The invention further relates to an axle counting system.

### Background of the Invention

By way of example, an axle counting method is known from EP 2 899 093 B1.

Axle counters are used to report track vacancy. Passing axles are detected by means of rail contact elements.

Axle counting devices and methods are used in railway signaling to detect the number of passing axles of a train. The information thus obtained is processed by one of the evaluation devices to determine whether route sections are vacant or occupied. The sensor elements used for this purpose generally comprise among other things a transmission device and a receiving device, which are mounted on opposite sides of a rail. The receiving devices generate a magnetic field, which is disturbed in the event of a passing axle. This disturbance is detected as a wheel pulse. The sensor elements form a so-called “rail contact element”.

Conventional axle counters with electromagnetic sensors are sensitive when the wheels are close to the sensor or pass the sensor very slowly. External disturbances, such as return traction currents or radiated fields from units in the operating frequency of the axle counter, can lead to incorrect axle evaluation. This is particularly a problem in train station areas where it is very likely that wheels will come to a stop near the axle counting sensor, or only pass it very slowly. This can result in disrupted axle counter sections with subsequent delays.

In principle, the problem could be solved by pattern recognition that can distinguish between wheels and return traction currents. However, such solutions would be very complex.

EP 2 899 093 B1 discloses a method for operating an axle counting system using redundant axle counting points (rail contact element and evaluation electronics) and an individual selection of the axle counting points for each axle counting point position, independently of the selection at other axle counting point positions. The provided redundancy allows disturbances to be detected. For this purpose, two transmission devices are used for each counting point that transmit signals at different frequencies (28 kHz, 30 kHz). By using different frequencies, two independent channels are generated to prevent crosstalk. However, a redundant design of the axle counting points means high material outlay.

### SUMMARY OF THE INVENTION

### Object of the Invention

It is an object of the invention to propose an axle counting method with which external disturbances can be distinguished from wheel signals in a simple and cost-effective manner.

### Description of the Invention

This object is achieved according to the invention by a method according to claim 1 and by an axle counting system according to claim 7.

In the axle counting method according to the invention, a single transmission unit is used to generate the transmission signal. According to the invention, the reception signals received by the two receiving units originate from the same transmission signal.

Using a single transmission unit ensures that possible external disturbances will always be reflected in the same way in both reception signals, and reduced occupancy of the frequencies in the band.

By detecting the same transmission signal using two spatially separated receiving units, two reception signals result. When a wheel travels between the transmission device and the two receiving units, the influence of the passing wheel on the transmission signal is time-shifted due to the spatial separation of the two receiving units—i.e., it is detected with a time-shift. External signals not belonging to the transmission signal are received equally by both receiving units, since both receivers receive signals on the same frequency. In this way, signals caused by external disturbances can be distinguished from wheel signals (i.e., signals caused by wheels passing the rail contact element). A redundant design of the rail contact elements can be dispensed with.

The signal processing unit processes the reception signals so that they can be interpreted/evaluated by an evaluation logic. The evaluation logic compares evaluation signals with a threshold value and interprets an exceeding of the threshold value as a passage of an axle.

The two adjacent receiving units, preferably coils, form a receiving device in the form of a double sensor.

Preferably, the evaluation signals of the two spatially separated receiving units are evaluated in a phase-inverted manner, which allows error detection for the transmission of the reception signals as well as error correction for disturbances. The phase-inverted evaluation can be realized by the type of evaluation (e.g., subtraction of the two reception signals), by signal processing or by phase inversion (i.e., a phase shift of) 180° before signal processing. The phase-inverted evaluation can detect an unwanted mutual influence between the two reception signals (crosstalk).

For this purpose, a particularly preferred variant of the method according to the invention provides that an inversion of the phase of one of the reception signals is generated before the transmission of the reception signals. This creates two channels independent of each other, even though the two reception signals have the same frequency. In this way, crosstalk can be reliably ascertained. This is, in particular, advantageous in critical sections in which the transmission cable can be easily damaged, which increases the risk of crosstalk. A “critical section” is to be understood as a section, or a portion of a section, over which the signal is to be transmitted, on which crosstalk is likely if no countermeasures are taken. Such sections are, in particular, connections between the frequency source and the transmission device, between the transmission device and the receiving units, and between the receiving units and the components for signal processing. In a preferred variant of the method according to the invention, the transmission of the electromagnetic reception signals (AC signals) therefore takes place over such a critical section.

Preferably, the phase inversion is carried out before the transmission of the reception signals by connecting the receiving units in opposite polarity. For this purpose, the receiving units are connected to the input of the signal processing unit with opposite polarities (cross-wire configuration).

In a special variant of the method, the phase inversion is removed after the transmission of the reception signals, in particular, by phase-synchronous rectification to the same transmission signal. Whether or not removal of the phase inversion is provided depends on how the signals are further processed, in particular, whether the reception signals are later subtracted from one another or added to one another. In the latter case, removal of the phase inversion is unnecessary. The rectification occurs regardless of which channel was used to transmit the reception signals.

Alternatively, a phase inversion can also be generated via software.

Preferably, phase-inverted synchronization signals are generated and used for the synchronous rectification, in particular, square-wave signals phase-shifted by 180°. In phase-synchronous rectification, the phase positions of the synchronization signals are compared with the phase positions of the reception signals. Without influences (i.e., without a passing wheel or external disturbances), a constant signal results from the synchronization process and after low-pass filtering.

If there is an influence, the field lines of the magnetic field generated by the transmission unit, which run through the receiving units are deflected, which can lead to a phase shift or even a signal inversion of the reception signal during the period of influence. The low-pass filtering “removes” the transmission frequency, which allows the different receivers, which are influenced differently by the wheel in spatial terms, to be evaluated. Due to the synchronization process and the low-pass filtering, a signal deviating from the constant signal is produced for each receiving unit during the respective periods of influence.

In the event of unwanted electromagnetic influence, both receiving units are usually influenced during the same period. In the event of a wheel influence due to a passing train, the receiving units are influenced with a time-shift. The rectification of the reception signals enables a subsequent differentiation between the two reception signals.

Preferably, a difference signal of the two synchronized reception signals is formed as an evaluation signal in the signal processing unit.

In the case of unwanted electromagnetic influence, a constant signal, in particular, a zero line results as the difference signal. In the event of a wheel influence due to a passing train, a non-vanishing difference signal results due to the time-shifted influence.

The difference signal is preferably generated using the rectified reception signals. Alternatively, the non-rectified signals could be used and then rectified.

If an inversion takes place before the transmission of the reception signals to the signal processing unit, the difference signal can be generated by adding the inverted reception signals, or by removing the inversion and then subtracting the no-longer-inverted reception signals.

If no inversion takes place before the transmission of the reception signals, the difference signal is generated by subtracting the two reception signals. In the latter variant, non-inverted reception signals are initially generated by connecting the receiving units with the same polarity; the non-inverted reception signals are transmitted to the signal processing unit for further processing.

The invention also relates to an axle counting system for carrying out a method described above, the axle counting system comprising:
an electromagnetic rail contact element having an electromagnetic transmission device and two spaced-apart electromagnetic receiving units,
a frequency source for producing a transmission signal for the electromagnetic transmission device, wherein the frequency source is electrically connected to the transmission device of the rail contact element,
an evaluation circuit for determining an axle passage having a signal processing unit for producing an evaluation signal from the two reception signals.

According to the invention, the transmission device has a single transmission unit.

During operation, the rail contact element is attached to a rail of a track and comprises a transmitter generating an alternating electromagnetic field, and two receiving units that receive the alternating electromagnetic field. The evaluation circuit detects the change in the alternating electromagnetic field in the reception signals caused by a wheel rolling past on the rail by generating an evaluation signal from the two reception signals. The evaluation signal is compared with a threshold value, and if the threshold value is exceeded it is interpreted as an axle passage and is fed as a counting pulse to a track vacancy reporting device.

An evaluation logic can be provided to evaluate the evaluation signal.

A particularly preferred embodiment provides that the receiving units of the rail contact element are connected to the evaluation circuit with different polarity. This causes a phase inversion of one of the reception signals so that the two reception signals can be transmitted independently of each other to the signal processing unit.

A further preferred embodiment provides that a synchronization device is present for removing the specified phase shift of the reception signals, which is electrically connected between the receiving units and the signal processing unit. This allows a previously applied phase inversion to be reversed.

Preferably, the frequency source is configured to generate a synchronization signal and an inverted synchronization signal and is connected by signaling connection to the synchronization device. The phase inversion is reversed by comparing the phase position of the synchronization signals with the phase positions of the corresponding reception signals.

Preferably, the signal evaluation device comprises a difference signal device. The difference signal device is used to eliminate external disturbances.

Furthermore, it is advantageous if the signal evaluation device comprises a comparator. The comparator compares an analog (optionally processed) reception signal to whether it falls below a fixed switching threshold and is used to detect when a wheel is exactly between the two receiving units, since this could be compensated for in the difference signal.

Preferably, the synchronization device comprises rectifiers.

Furthermore, it can be advantageous if low-pass filters are present between the synchronization device and the signal processing unit. The low-pass filters are used to eliminate higher frequencies (preferably >130 Hz) which definitely cannot be attributed to wheel influences.

Further advantages of the invention can be found in the description and the drawings. Likewise, according to the invention, the aforementioned features and those which are to be explained below can each be used individually or together in any desired combinations. The embodiments shown and described are not to be understood as an exhaustive list, but, rather, have an exemplary character for the description of the invention.

### BRIEF DESCRIPTION OF THE DRAWINGS

FIG. 1 shows a schematic illustration of the components and the method steps of a simple embodiment of the axle counting system according to the invention.

FIG. 2 shows a schematic illustration of the components and the method steps of a further embodiment of the axle counting system according to the invention, with additional activation detection and low-pass filtering.

FIG. 3 shows a schematic illustration of the components and the method steps of a particularly preferred embodiment of the axle counting system according to the invention, with phase inversion.

FIG. 4 shows the interconnection of the receiving units of FIG. 3.

FIG. 5 shows the signal processing and evaluation of reception signals with wheel detection and external disturbances, without phase inversion, according to FIG. 2.

### DETAILED DESCRIPTION OF EMBODIMENTS OF THE INVENTION

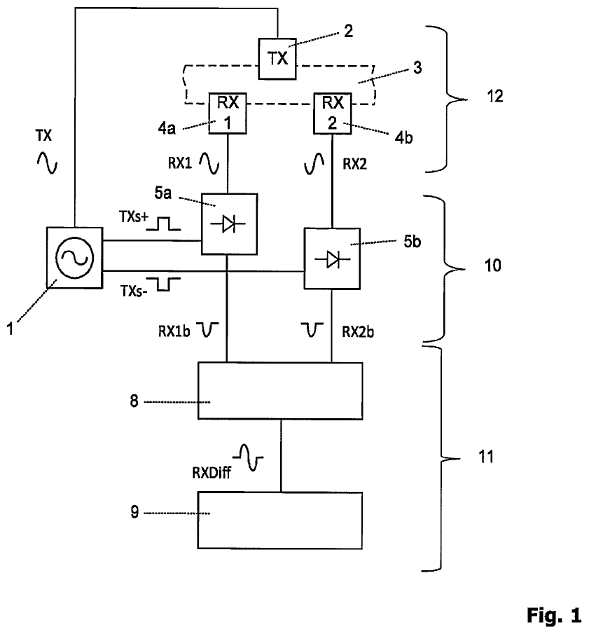

FIG. 1 shows a simple variant of the method according to the invention and the components of the axle counting system according to the invention. A frequency source 1 serves to generate a frequency for a transmission device with a transmission unit 2. The transmission unit 2 is arranged on a rail 3 and transmits a transmission signal TX. From the transmission unit 2, the electromagnetic field of the transmission signal TX spreads around the rail 3 and is received by two spatially separated receiving units 4a, 4b of a receiving device. The transmission unit 2 and the receiving units 4a, 4b form a rail contact element 12. The first receiving unit 4a receives the transmission signal TX in the form of a first reception signal RX1; the second receiving unit 4b receives the transmission signal TX in the form of a second reception signal RX2. In the method according to the invention, the transmission device 2 comprises only a single transmission unit 2. The first receiving unit 4a therefore receives on the same frequency as the second receiving unit 4b. This allows both reception signals to be synchronized with the same transmission signal.

The transmission unit 2 is preferably arranged centrally between the receiving units 4a, 4b, and can preferably be arranged on the side of the rail 3 opposite the receiving units 4a, 4b. The two receiving units 4a, 4b are spatially separated from each other along the longitudinal extension of the rail 3. In this way, the first reception signal RX1 received by the first receiving unit 4a is influenced by a passing wheel at a different time than that of the second reception signal RX2 received by the second receiving unit 4b.

In addition to the transmission signal TX, the frequency source 1 also generates synchronization signals TXs+, TXs− which are in phase or phase-inverted with respect to the transmission signal TX. The synchronization signals are preferably square wave signals.

The signal processing of the two reception signals RX1, RX2 is carried out via two channels independent from each other, and includes, in particular, phase-synchronous rectification. For this purpose, the synchronization signals TXs+, TXs− are relayed as reference signals to synchronous rectifiers 5a, 5b. The rectifiers 5a, 5b form input rectifiers of the signal processing unit 10. The signal processing unit 10 further comprises a difference signal generation unit 8 by means of which a difference signal RXdiff is generated from the synchronized reception signals RX1b, RX2b. The difference signal RXdiff can be used to determine, independently of external disturbances, whether a wheel has passed the rail contact element 12.

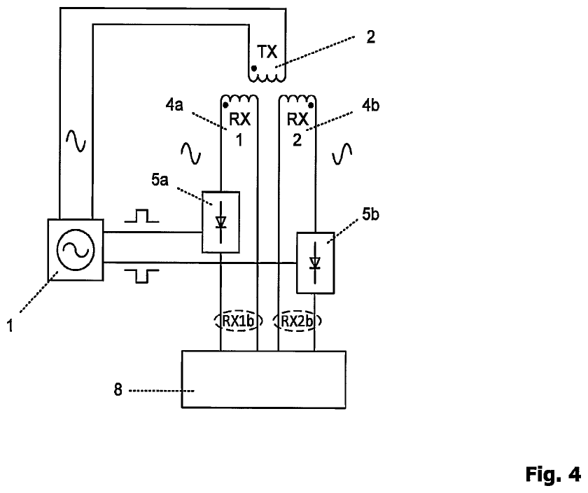

In the example shown in FIG. 1, phase-inverted reception signals RX1, RX2 are generated, i.e., reception signals that have a phase shift of 180° to each other. For this purpose, the receiving units 4a, 4b are connected with opposite polarity. The associated circuit is shown in detail in FIG. 4. While in the first channel the phase-synchronous rectifier 5a is connected to the coil start (marked with a dot) of the coil serving as the first receiving unit 4a, in the second channel, the phase-synchronous rectifier 5b is connected to the coil terminus of the coil serving as the second receiving unit 4b. The coils of the two receiving devices 4a, 4b are therefore powered in different winding directions. This results in a phase shift of the second reception signal of 180° compared to the reception signal that would be obtained if the second receiving unit were connected by its coil start to the rectifier 5b. Since both receiving units 4a, 4b receive the same transmission signal, the two reception signals also have a phase shift of 180° to each other.

In the present example (but not absolutely necessary), in phase-synchronous rectification, the channel of the second reception signal RX2 is evaluated in antiphase to the channel of the first reception signal RX1. For this purpose, two synchronization signals TXs+, TXs− are first generated by the same frequency source 2, which is also used to generate the transmission signal, and these also have a phase shift of 180° to each other and are in phase respectively phase-inverted to the transmission signal TX. The phase inversion is therefore removed by the synchronization of the reception signals RX1, RX2 with the synchronization signals TXs+, TXs−.

In order to generate a difference signal RXdiff by means of the difference signal generation unit 8, the signal-processed analog evaluation signals RX1b, RX2b are subtracted from one another in the difference signal generation unit 8. The evaluation of the difference signal RXdiff is carried out in an evaluation logic 9.

In the following, the invention is described with reference to further exemplary embodiments of the axle counting system according to the invention and method variants. The same reference signs as in FIG. 1 are used for the same parts.

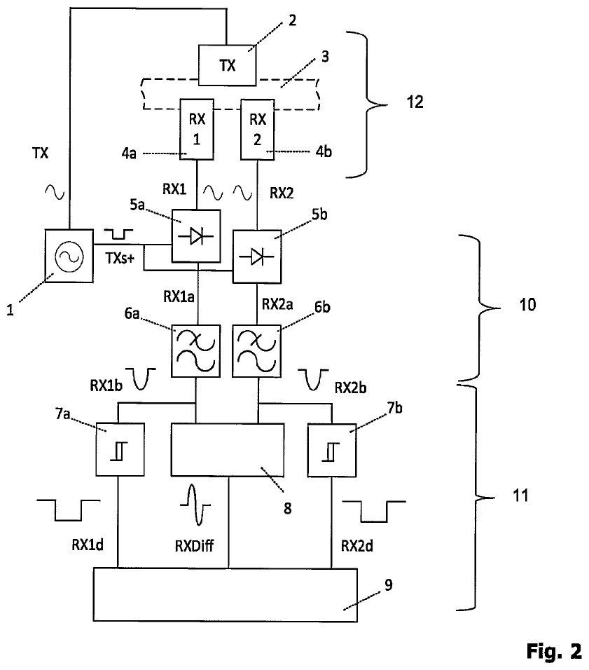

FIG. 2 shows a variant of the method according to the invention and the components of the axle counting system according to the invention, in which no phase inversion of the reception signals RX1, RX2 takes place. Therefore, only a single synchronization signal TXs+ is generated to rectify the reception signals RX1, RX2.

FIG. 2 also shows a method variant with extended signal processing and evaluation. In contrast to the variant shown in FIG. 1, the reception signals RX1, RX2 are not only rectified to generate the analog evaluation signals RX1b, RX2b, but are also low-pass filtered after rectification. For this purpose, the axle counting device according to the invention comprises low-pass filters 6a, 6b. After rectification, the analog evaluation signals RX1b, RX2b are not yet available, but rather intermediate signals RX1a, RX2a in this method variant.

When evaluating the analog evaluation signals RX1b, RX2b, in addition to generating the difference signal RXdiff, an activation detection is carried out by means of comparators 7a, 7b. For this purpose, one comparator 7a, 7b is used per channel, which performs a wheel detection for each reception signal (by generating activation signals RX1d, RX2d). The activation signals RX1d, RX2d and the difference signal RXdiff are evaluated in the evaluation logic 9.

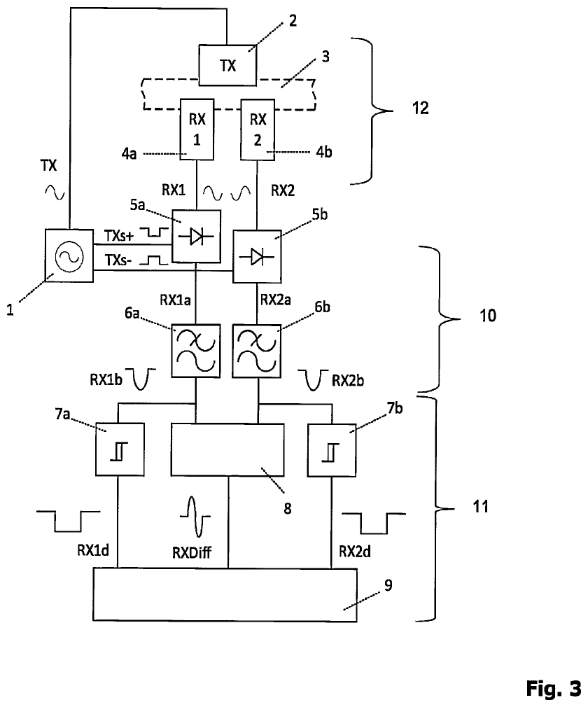

FIG. 3 shows a particularly preferred variant of the method according to the invention, and the components of the axle counting system according to the invention in which, in addition to the extended signal processing and the extended evaluation as in the variant shown in FIG. 2, a phase inversion of the second reception signal RX2 also takes place (as in the variant shown in FIG. 1).

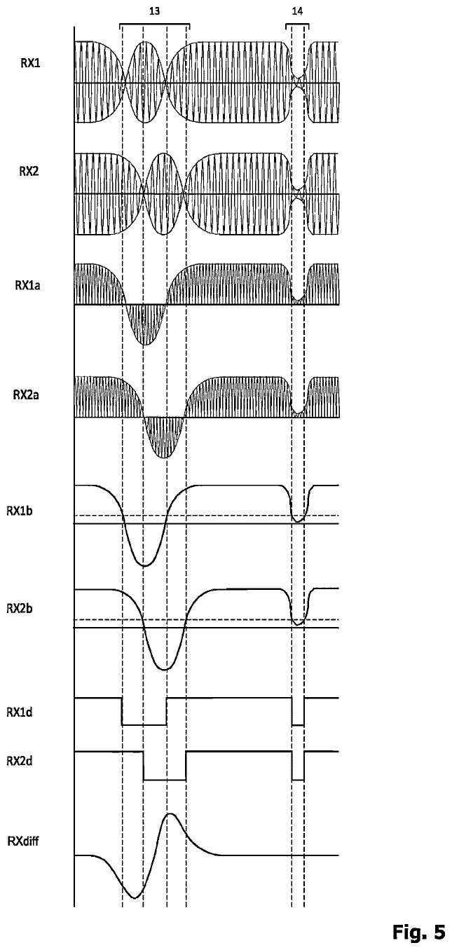

FIG. 5 shows the signals in different stages of signal processing and evaluation in an axle counting system according to FIG. 2. In the time period shown in FIG. 5, there was first an influence by a passing wheel (signal region 13) and then by an external disturbance (signal region 14). The influence on the reception signals is, in particular, noticeable through a change in the amplitude, which can be seen in FIG. 5 from the change in shape of the envelopes of the reception signals. The two reception signals RX1, RX2 are influenced by the passing wheel with a time shift, while the external disturbance occurs in both reception signals RX1, RX2 simultaneously. After phase-synchronous rectification, intermediate signals RX1a, RX2a are obtained. After low-pass filtering, analog evaluation signals RX1b, RX2b are obtained which correspond to the envelope curve of the intermediate signals. The influences are clearly visible as local minima.

The digital activation signals RX1d, RX2d, preferably generated by comparators, are used to monitor the sensor (transmission device and receiving units) at rest (activation detection). This additional information on the difference signal RXdiff is used, among other things, to detect a wheel parked in the region of the sensor in a region between the receiving units.

By subtracting the two evaluation signals, the difference signal RXdiff is generated, from which the influence by the passing wheel (signal region 13) is clearly recognizable, since this occurred with a time-shift for the two receiving units 4a, 4b. However, the influence due to the external disturbance (signal region 14), which occurred simultaneously for both receiving units 4a, 4b, is no longer recognizable in the difference signal. It is therefore a disturbance-corrected signal. The method according to the invention achieves a desensitization of the axle counting points to signals other than the transmission signal (disturbances signals).

### LIST OF REFERENCE SIGNS

1 frequency source
2 transmission device
3 rail
4a first receiving unit
4b second receiving unit
5a, 5b rectifier
6a, 6b low-pass filter
7a, 7b comparators
8 difference signal generation unit
9 evaluation logic
10 signal processing unit
11 evaluation circuit
12 rail contact element
13 signal region influenced by a passing wheel
14 signal region influenced by an external disturbance
RX1 first reception signal
RX2 second reception signal
RX1a first synchronized reception signal
RX2a second synchronized reception signal
RX1b first analog rectified reception signal
RX2b second analog rectified reception signal
RX1d first digital activation signal
RX2d second digital activation signal
TXs+, TXs− synchronization signals
RXdiff difference signal (evaluation signal)
Literature List:
EP 2 899 093 B1

What is claimed is:

1. An axle counting method for rail-mounted vehicles, having the following method steps:
producing an electromagnetic transmission signal with a frequency, by a frequency source;
transmitting the electromagnetic transmission signal by a transmission device of an electromagnetic rail contact element;
detecting the electromagnetic transmission signal as a first reception signal and a second reception signal by two spaced-apart receiving units of the rail contact element;
transmitting the reception signals;
generating an evaluation signal within a signal processing unit;
wherein to generate the transmission signal, a single transmission unit is used, and in that the reception signals received by the two receiving units originate from the same transmission signal.

2. The method according to claim 1, wherein the reception signals are evaluated in a phase-inverted manner.

3. The method according to claim 2, wherein an inversion of the phase of one of the reception signals is generated before the transmission of the reception signals.

4. The method according to claim 3, wherein the phase inversion takes place before the transmission of the reception signals by connecting the receiving units in opposite polarity.

5. The method according to claim 1, wherein the phase inversion is removed after the transmission of the reception signals by phase-synchronous rectification to the same transmission signal.

6. The method according to claim 5, wherein phase-inverted synchronization signals, being square-wave signals phase-shifted by 180°, are generated and used for the synchronous rectification.

7. The method according to claim 2, wherein a difference signal of the two synchronized reception signals is formed as an evaluation signal in the signal processing unit.

8. The method according to claim 1, wherein a comparison with a fixed threshold value takes place in the signal processing unit.

9. An axle counting system for carrying out the method according to claim 1, wherein the axle counting system comprises:
the electromagnetic rail contact element having the transmission device and the two spaced-apart electromagnetic receiving units;
the frequency source for generating the transmission signal for the electromagnetic transmission device, wherein the frequency source is electrically connected to the transmission device of the rail contact element;
an evaluation circuit configured for determining an axle passage having the signal processing unit configured for generating the evaluation signal from the two reception signals; and
wherein the transmission device has the single transmission unit.

10. The axle counting system according to claim 9, wherein the receiving units of the rail contact element are connected to the evaluation circuit with different polarity.

11. The axle counting system according to claim 9, wherein a synchronization device configured for removing the specified phase shift of the reception signals is present, and is electrically connected between the receiving units and the signal processing unit.

12. The axle counting system according to claim 11, wherein the frequency source is configured to generate two phase-shifted synchronization signals, and is connected by signaling connection to the synchronization device.

13. The axle counting system according to claim 9, wherein the signal evaluation device comprises a difference signal device.

14. The axle counting system according to claim 9, wherein the signal evaluation device comprises a comparator.

15. The axle counting system according to claim 9, wherein the synchronization device comprises rectifiers.

16. The axle counting system according to claim 9, wherein low-pass filters are present between the synchronization device and the signal processing unit.
